(19) United States
(12) Patent Application Publication
(10) Pub. No.: US 2026/0318355 A1
(43) Pub. Date: Oct. 15, 2026

(54) SLIDING RAIL HAVING LOCKING, SLIDING-IN, AND DISASSEMBLY OPENING-CLOSING MECHANISM AND METHOD OF USING SAME

(71) Applicant: Kunshan Lemtech Slide Technology Co., Ltd., Kunshan (CN)

(72) Inventor: Qifeng XU, Kunshan (CN)

(73) Assignee: Kunshan Lemtech Slide Technology Co., Ltd., Kunshan (CN)

(21) Appl. No.: 19/240,098

(22) Filed: Jun. 17, 2025

(30) Foreign Application Priority Data
Apr. 9, 2025 (CN) 2025104372711

(51) Int. Cl. F16C 29/10; F16C 29/02

(52) U.S. Cl. CPC F16C 29/10; A47B 88/423; A47B 88/483; A47B 88/57; F16C 29/02; H05K 7/1489; F16C 2314/72

(57) ABSTRACT

The present invention discloses a sliding rail having locking, sliding-in, and disassembly opening-closing mechanism and method of using the same. The sliding rail includes a first rail and a second rail slidably assembled relative to each other along a length direction, and a first locking block and a second locking block are mounted on a side surface of the second rail facing the first rail at intervals along a length direction; the first locking block and the second locking block are respectively driven by a sliding-in unlocking mechanism and a disassembly unlocking mechanism to move in a width direction of the second rail; and a limiting protrusion is disposed on a side surface of the first rail facing the second rail, and along with a relative sliding of the second rail and the first rail in the length direction.

### CROSS-REFERENCE TO RELATED APPLICATIONS

The application claims priority to Chinese patent application No. 2025104372711, filed on Apr. 9, 2025, the entire contents of which are incorporated herein by reference.

### TECHNICAL FIELD

The present invention relates to the technical field of sliding rails, and in particular, to a sliding rail having locking, sliding-in, and disassembly opening-closing mechanism and method of using the same.

### BACKGROUND

Common sliding rail devices include two-section sliding rails and three-section sliding rails, and the three-section sliding rails usually includes an outer rail, a middle rail and an inner rail. The outer rail is fixed to a server rack, the inner rail is fixed to two sides of the server, and the middle rail serves as a bearing rail to be connected between the outer rail and the inner rail to extend the movement range of the server, allowing the inner rail and the middle rail to slide back and forth relative to the outer rail along the length direction of the outer rail. Therefore, the server can be freely pulled out or pushed back through the sliding rail device.

In actual use, after the server slides out along with the inner rail, a locking mechanism needs to be arranged on the inner rail to prevent accidental sliding of the inner rail; and when the server is maintained, it is also necessary to disassemble the server for ease of operation.

In the prior art, a fixed limiting mechanism is usually arranged between the inner rail and the middle rail, so as to prevent the inner rail from accidentally sliding out or even being disengaged; and when the server needs to be disassembled and maintained, the server is directly disassembled from the inner rail, or force is applied to cause the inner rail to cross the limiting mechanism and then be synchronously disassembled along with the server, which is quite inconvenient, and the inner rail is prone to being damaged due to forced disassembly under load.

### SUMMARY

In order to solve the above problem, the present invention provides a sliding rail with a reasonable structure and having a locking, sliding-in, and disassembly opening-closing mechanism and method of using the same, so that the sliding-in or disassembly operation can be achieved while reliable locking in a sliding-out state of the sliding rail is ensured. The operation is convenient and smooth, which greatly ensures and facilitates daily maintenance and use of a server, and has good practicability.

Technical solutions adopted by the present invention are as follows: a sliding rail having a locking, sliding-in, and disassembling and opening-closing mechanism includes a first rail and a second rail slidably assembled relative to each other along a length direction, where a first locking block and a second locking block are mounted on a side surface of the second rail facing the first rail at intervals along a length direction; the first locking block is driven by a sliding-in unlocking mechanism to move in a width direction of the second rail, and the second locking block is driven by a disassembly unlocking mechanism to move in the width direction the second rail; and a limiting protrusion is disposed on a side surface of the first rail facing the second rail, and along with a relative sliding of the second rail and the first rail in the length direction, the limiting protrusion is clamped between the first locking block and the second locking block to form bidirectional locking of the second rail and the first rail in a sliding direction.

As a further improvement of the above technical solution: the sliding-in unlocking mechanism includes a long push rod slidably arranged along a length direction of the second rail, an inner end of the long push rod is located at the first locking block, a wedge surface fit is formed between an end portion of the long push rod and the first locking block, and movement of the long push rod in a length direction causes the first locking block to move to unlock in the width direction of the second rail.

A first guide structure and a first reset structure for relative sliding are mounted between the long push rod and the second rail as well as between the first locking block and the second rail; and the end portion of the long push rod facing the first locking block is disposed as a first sliding-in inclined surface, and the first sliding-in inclined surface and a second sliding-in inclined surface on the first locking block are assembled to form a wedge surface fit.

A sliding-in trigger mechanism is mounted at an end portion of the second rail located at an outer end of the long push rod, and the sliding-in trigger mechanism pushes the long push rod to move to cause the first locking block to move.

The sliding-in trigger mechanism includes a push plate slidably mounted on a side surface at the end portion of the second rail, an inner side surface of the push plate directly faces the outer end of the long push rod, and an outer side surface of the push plate extends out of the second rail and then turns over and extends to form a pushing portion; and a second guide structure and a second reset structure for relative sliding are mounted between the push plate and the second rail.

The disassembly unlocking mechanism includes a short pull rod slidably arranged along the length direction of the second rail, the short pull rod pass through the second locking block along the length direction, a wedge surface fit is formed between the short pull rod and the second locking block, and movement of the short pull rod in the length direction causes the second locking block to move to unlock in the width direction of the second rail.

A third guide structure and a third reset structure for relative sliding are mounted between the second locking block and the second rail, and a fourth guide structure for relative sliding is mounted between the short pull rod and the second rail; and a first disassembly inclined surface is formed in a middle portion of the short pull rod, a second through groove for the short pull rod to pass through is formed in the second locking block, and a second disassembly inclined surface assembled with the first disassembly inclined surface is formed on a side surface of the second through groove to form a wedge surface fit.

A disassembly trigger mechanism is mounted at an end portion of the short pull rod away from the second locking block, and the disassembly trigger mechanism is mounted at a middle portion of the second rail; and when the first rail and the second rail are bidirectionally locked in the sliding direction, the disassembly trigger mechanism is located outside an end portion of the first rail.

The end portion of the short pull rod extends to form a mounting portion, and the disassembly trigger mechanism is a toggle block assembled on a side surface of the mounting portion; and the mounting portion and a side surface attached to the toggle block are clamped and matched through a concave hole and a convex block, and a fastener is mounted towards the mounting portion through the toggle block.

A method of using of the sliding rail having a locking, sliding-in, and disassembly opening-closing mechanism includes the following steps:
enabling a second rail to slide out relative to a first rail along a length direction until a limiting protrusion on a side surface of the first rail crosses a first locking block on a side surface of the second rail, where the limiting protrusion is clamped between the first locking block and the second locking block, so that the second rail is bidirectionally locked in a sliding direction relative to the first rail;
pushing a long push rod in a sliding-in unlocking mechanism to drive the first locking block to move along a width direction of the second rail to disengage from the locking of the limiting protrusion, so that the second rail can slide in relative to the first rail; and
pulling a short pull rod in a disassembly unlocking mechanism to drive the second locking block to move along the width direction of the second rail to disengage from the locking of the limiting protrusion, so that the second rail can continue to move along a slide-out direction relative to the first rail until the second rail is disengaged from the first rail to achieve disassembly.

Compared with the prior art, the present invention has the following beneficial effects:
according to the present invention, reliable locking in the sliding direction can be effectively ensured after the second rail slides out relative to the first rail, and sliding-in or disengaging of the second rail relative to the first rail can be achieved through unlocking of the first locking block or the second locking block according to actual requirements, and the operation is convenient and smooth, which greatly ensures and facilitates daily maintenance and use of a server, and has good practicability; and
the present invention further includes the following advantages:
the sliding-in trigger mechanism pushed by the long push rod in the sliding-in unlocking mechanism is arranged at the outer end portion of the second rail, through pushing of the push plate at the end portion, unlocking of the first locking block close to the inner end portion of the second rail is achieved through force transmission, thereby facilitating force application operation in practice, and ensuring smooth unlocking; and
the disassembly trigger mechanism pulled by the short pull rod in the disassembly unlocking mechanism is arranged at the middle portion of the second rail, by manually applying a force to the disassembly trigger mechanism, unlocking of the second locking block is achieved through force transmission; and compared with the force applied by the sliding-in trigger mechanism, the operation of the disassembly trigger mechanism is finer, and manual operation is required, which conforms to the actual usage scenarios, and effectively avoids misoperation on the disassembly trigger mechanism.

### BRIEF DESCRIPTION OF THE DRAWINGS

FIG. 1 is a structural outline view of the present invention;

FIG. 2 is a schematic structural diagram of a limiting protrusion on a first rail according to the present invention;

FIG. 3 is a schematic layout diagram of a sliding-in unlocking mechanism and a disassembly unlocking mechanism on a side surface of a second rail according to the present invention;

FIG. 4 is an exploded view of FIG. 3;

FIG. 5 is a partial enlarged view of a position A in FIG. 4;

FIG. 6 is a schematic diagram of an installation of a short pull rod and a support block and a disassembly trigger mechanism according to the present invention; and

FIG. 7 is a schematic structural diagram of a second locking block according to the present invention.

In the accompanying drawings: 1. sliding-in trigger mechanism; 2. sliding-in unlocking mechanism; 3. disassembly trigger mechanism; 4. disassembly unlocking mechanism; 10. first rail; 20. second rail; 101. limiting protrusion;
11. end plate; 12. push plate; 13. convex column; 14. fifth guide pin; 15. second support; 16. fourth elastic member; 17. limiting block; 121. second long hole; 122. pushing portion;
21. long push rod; 22. first guide pin; 23. first elastic member; 24. second guide pin; 25. first locking block; 26. support block; 27. middle block; 28. second elastic member; 211. first long hole; 212. first protruding portion; 213. first sliding-in inclined surface; 251. second sliding-in inclined surface; 261. first through groove; 262. limiting groove;
41. short pull rod; 42. third guide pin; 43. third elastic member; 44. first support; 45. second locking block; 46. fourth guide pin; 411. first disassembly inclined surface; 412. second protruding portion; 413. mounting portion; 414. third long hole; 451. guide inclined surface; 452. clamping block; 453. fourth long hole; 454. through hole; 455. second through groove; 456. second disassembly inclined surface.

### DETAILED DESCRIPTION OF THE EMBODIMENTS

The specific embodiments of the present invention are described below with reference to the accompanying drawings.

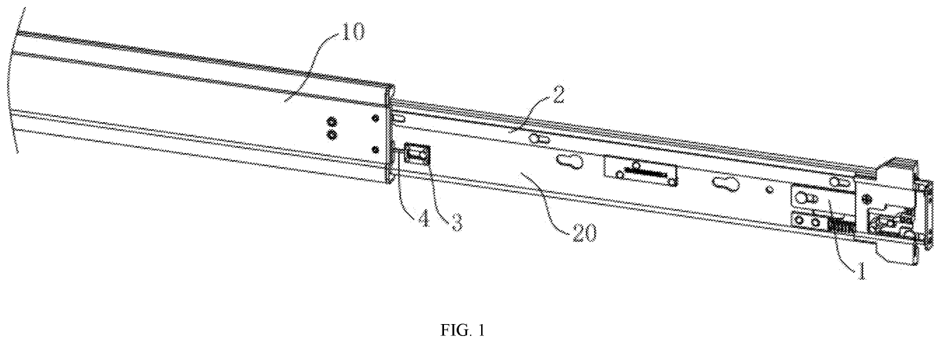

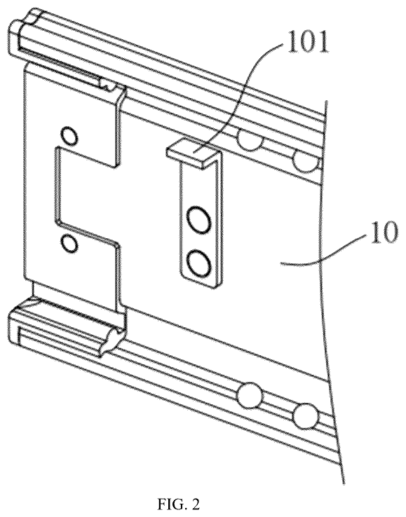

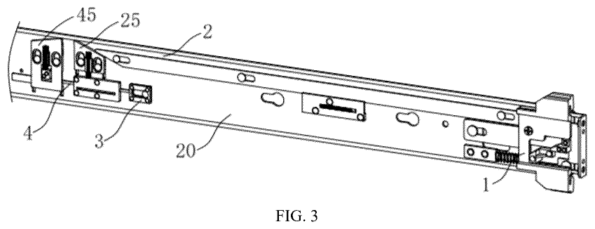

As shown in FIG. 1, FIG. 2, and FIG. 3, a sliding rail having a locking, sliding-in, and disassembly opening-closing mechanism of this embodiment includes a first rail 10 and a second rail 20 slidably assembled relative to each other along a length direction, where a first locking block 25 and a second locking block 45 are mounted on a side surface of the second rail 20 facing the first rail 10 at intervals along a length direction; the first locking block 25 is driven by a sliding-in unlocking mechanism 2 to move in a width direction of the second rail 20, and the second locking block 45 is driven by a disassembly unlocking mechanism 4 to move in the width direction the second rail 20; and a limiting protrusion 101 is disposed on a side surface of the first rail 10 facing the second rail 20, and along with a relative sliding of the second rail 20 and the first rail 10 in the length direction, the limiting protrusion 101 is clamped between the first locking block 25 and the second locking block 45 to form bidirectional locking of the second rail 20 and the first rail 10 in a sliding direction.

In this embodiment, during actual operation, reliable locking in the sliding direction can be effectively ensured after the second rail 20 slides out relative to the first rail 10, and sliding-in or disengaging of the second rail 20 relative to the first rail 10 can be achieved through unlocking of the first locking block 25 or the second locking block 45 according to actual requirements.

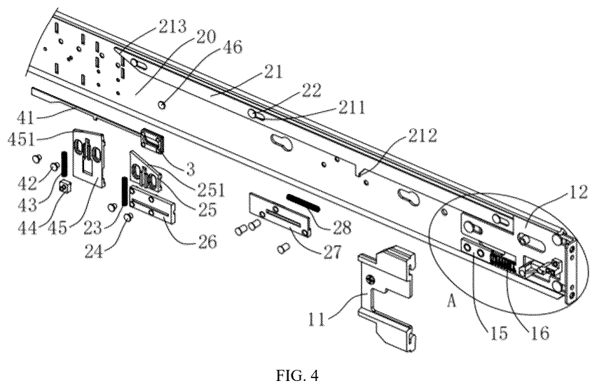

As shown in FIG. 4, the sliding-in unlocking mechanism 2 includes a long push rod 21 slidably arranged along a length direction of the second rail 20, an inner end of the long push rod 21 is located at the first locking block 25, a wedge surface fit is formed between an end portion of the long push rod 21 and the first locking block 25, and movement of the long push rod 21 in a length direction causes the first locking block 25 to move to unlock in the width direction of the second rail 20; and therefore, through the long push rod 21, and in combination with the wedge surface fit, remote force transmission control of unlocking of the first locking block 25 can be achieved, and the reliability of locking and unlocking is ensured through the wedge surface fit.

In this embodiment, a moving direction of the long push rod 21 relative to the second rail 20 is along the length direction of the second rail 20, and a moving direction of the first locking block 25 relative to the second rail 20 is along the width direction of the second rail 20, so that the first locking block 25 is driven to move through the force transmitted by the long push rod 21 by effectively combining and using the wedge surface fit.

A first guide structure and a first reset structure for relative sliding are mounted between the long push rod 21 and the second rail 20 as well as between the first locking block 25 and the second rail 20; and the end portion of the long push rod 21 facing the first locking block 25 is disposed as a first sliding-in inclined surface 213, and the first sliding-in inclined surface 213 and a second sliding-in inclined surface 251 on the first locking block 25 are assembled to form a wedge surface fit.

In this embodiment, a plurality of first long holes 211 are formed in the length direction of the long push rod 21 at intervals, a first guide pin 22 correspondingly passing through each first long hole 211 is mounted on the second rail 20, and the relative movement of the first guide pin 22 in the corresponding first long hole 211 forms the first guide structure for relative movement between the long push rod 21 and the second rail 20.

In this embodiment, a second elastic member 28 is mounted between the middle portion of the long push rod 21 and the second rail 20, and the second elastic member 28 ensures the reset of the long push rod 21 after the long push rod moves to unlock, forming the first reset structure after the long push rod 21 and the second rail 20 move relative to each other.

In an embodiment, a middle block 27 is mounted on a side surface of the second rail 20 located in the middle portion of the long push rod 21, and the long push rod 21 passes through between the middle block 27 and the second rail 20; and the long push rod 21 extends in the width direction of the second rail 20 to form a first protruding portion 212, and a second elastic member 28 arranged along the length direction of the long push rod 21 is mounted between the first protruding portion 212 and the middle block 27.

In this embodiment, a long hole arranged along the width direction of the second rail 20 is formed in the first locking block 25, and a second guide pin 24 is mounted towards the second rail 20 through the long hole, so that the first locking block 25 can move in the width direction relative to the second rail 20 under the guidance of the fitting of the second guide pin 24 and the long hole, forming the first guide structure for relative movement between the first locking block 25 and the second rail 20.

In this embodiment, a support block 26 is mounted on the second rail 20 located at the end portion of the first locking block 25 in the moving direction, and a first elastic member 23 is mounted between the first locking block 25 and the support block 26, and the first elastic member 23 ensures the reset of the first locking block 25 after the first locking block moves to unlock relative to the second rail 20, forming the first reset structure after the first locking block 25 and the second rail 20 move relative to each other.

In this embodiment, the second sliding-in inclined surface 251 on the first locking block 25 is used for forming a wedge surface fit between the second sliding-in inclined surface and the long push rod 21, and in addition, in the slide-out operation of the second rail 20 relative to the first rail 10, as the sliding is carried out, the limiting protrusion 101 on the first rail 10 applies force to the first locking block 25 through the second sliding-in inclined surface 251 to drive the first locking block 25 to move relative to the second rail 20, until the limiting protrusion 101 crosses the first locking block 25 to achieve locking in the sliding-out state; and the second sliding-in inclined surface 251 effectively ensures that the locking is achieved through the limiting protrusion 101.

A sliding-in trigger mechanism 1 is mounted at an end portion of the second rail 20 located at an outer end of the long push rod 21, and the sliding-in trigger mechanism 1 pushes the long push rod 21 to move to cause the first locking block 25 to move.

In this embodiment, the sliding-in trigger mechanism 1 is arranged at the end portion of the second rail 20, which facilitates performing operation on the long push rod 21, and the long push rod 21 transmits force to achieve remote unlocking of the first locking block 25.

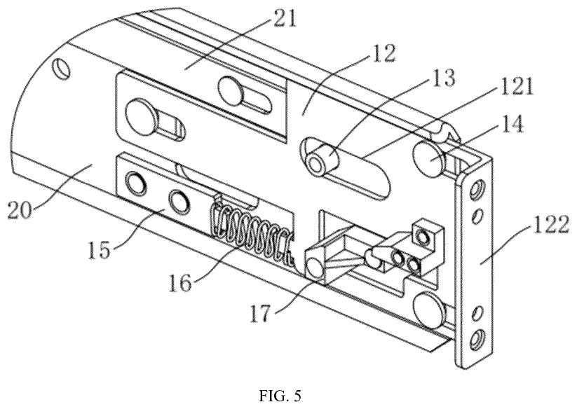

As shown in FIG. 5, the sliding-in trigger mechanism 1 includes a push plate 12 slidably mounted on a side surface at the end portion of the second rail 20, an inner side surface of the push plate 12 directly faces the outer end of the long push rod 21, and an outer side surface of the push plate 12 extends out of the second rail 20 and then turns over and extends to form a pushing portion 122, which facilitates pushing of the push plate 12 and the long push rod 21.

In this embodiment, the sliding-in trigger mechanism 1 pushed by the long push rod 21 in the sliding-in unlocking mechanism 2 is arranged at the outer end portion of the second rail 20, through pushing of the push plate 12 at the end portion, unlocking of the first locking block 25 close to the inner end portion of the second rail 20 is achieved through force transmission, thereby facilitating force application operation in practice, and ensuring smooth unlocking.

A second guide structure and a second reset structure for relative sliding are mounted between the push plate 12 and the second rail 20.

In this embodiment, a plurality of second long holes 121 are formed in the push plate 12, a plurality of convex columns 13 or fifth guide pins 14 fixed to the second rail 20 are mounted through the second long hole 121, and the relative movement of the convex column 13 and the fifth guide pin 14 in the second long hole 121 forms the second guide structure for relative movement between the push plate 12 and the second rail 20.

In this embodiment, a second support 15 is further mounted at the side surface of the second rail 20, a fourth elastic member 16 is mounted between the second support 15 and the push plate 12, and the fourth elastic member 16 ensures the reset of the push plate 12 after the push plate moves to unlock, forming the second reset structure after the push plate 12 and the second rail 20 move relative to each other.

In this embodiment, a limiting block 17 is further mounted on the second rail 20, and the limiting block 17 can limit the movement reset of the push plate 12.

In this embodiment, an end plate 11 is mounted via the convex column 13, the end plate 11 is arranged parallel to the side surface of the second rail 20, and a space for accommodating and relatively moving the push plate 12 is formed between the end plate 11 and the second rail 20; and edges of the two sides of the end plate 11 extend towards edges of the two sides of the second rail 20 and are clamped and limited to each other.

The disassembly unlocking mechanism 4 includes a short pull rod 41 slidably arranged along a length direction of the second rail 20, the short pull rod 41 passes through the second locking block 45 along the length direction, a wedge surface fit is formed between the short pull rod 41 and the second locking block 45, and movement of the short pull rod 41 in a length direction causes the second locking block 45 to move to unlock in the width direction of the second rail 20; and therefore, through the short pull rod 41, and in combination with the wedge surface fit, remote force transmission control of unlocking of the second locking block 45 can be achieved, and the reliability and stability of locking and unlocking is ensured through the wedge surface fit.

In this embodiment, a moving direction of the short pull rod 41 relative to the second rail 20 is along the length direction of the second rail 20, and a moving direction of the second locking block 45 relative to the second rail 20 is along the width direction of the second rail 20, so that the second locking block 45 is driven to move through the force transmitted by the short pull rod 41 by effectively combining and using the wedge surface fit.

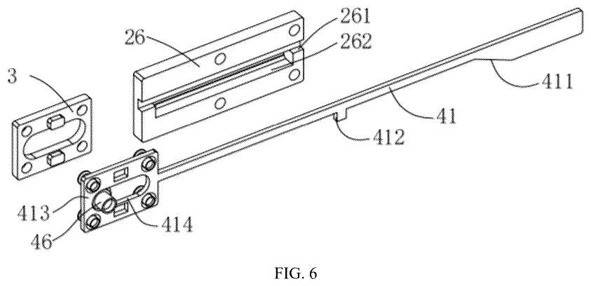

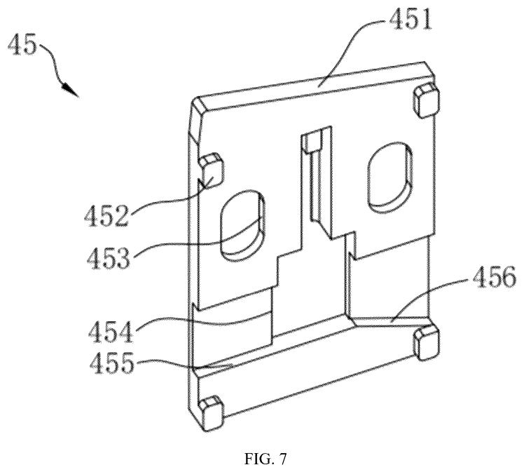

As shown in FIG. 6 and FIG. 7, a third guide structure and a third reset structure for relative sliding are mounted between the second locking block 45 and the second rail 20, and a fourth guide structure for relative sliding is mounted between the short pull rod 41 and the second rail 20; and a first disassembly inclined surface 411 is formed in a middle portion of the short pull rod 41, a second through groove 455 for the short pull rod 41 to pass through is formed in the second locking block 45, and a second disassembly inclined surface 456 assembled with the first disassembly inclined surface 411 is formed on a side surface of the second through groove 455 to form a wedge surface fit.

In this embodiment, a fourth long hole 453 arranged along the width direction of the second rail 20 is formed in the second locking block 45, and a third guide pin 42 is mounted towards the second rail 20 through the fourth long hole 453, so that the second locking block 45 can move in the width direction relative to the second rail 20 under the guidance of the fitting of the third guide pin 42 and the fourth long hole 453, forming the third guide structure for relative movement between the second locking block 45 and the second rail 20.

In this embodiment, a first support 44 is mounted on the second rail 20 located in the moving direction of the second locking block 45, and a third elastic member 43 is mounted between the second locking block 45 and the first support 44, and the third elastic member 43 ensures the reset of the second locking block 45 after the second locking block moves to unlock relative to the second rail 20, forming the third reset structure after the second locking block 45 and the second rail 20 move relative to each other.

A through hole 454 for accommodating and relatively moving the first support 44 is formed in the middle portion of the second locking block 45.

In this embodiment, a first through groove 261 for the short pull rod 41 to pass through is formed in the support block 26, the middle portion of the first through groove 261 extends downwards to form a limiting groove 262, the middle portion of the short pull rod 41 extends in the width direction of the second rail 20 to form a second protruding portion 412, and the second protruding portion 412 is assembled in the limiting groove 262 and moves relatively in the limiting groove 262; and a second through groove 455 for the short pull rod 41 to pass through is formed in the second locking block 45, and the first through groove 261 and the second through groove 455 are located on the same straight line, forming the fourth guide structure for relative movement between the short pull rod 41 and the second rail 20.

In this embodiment, an assembling structure can also be arranged on a side surface, facing the second rail 20, of the first locking block 25 and the second locking block 45 according to an actual design, for example, the protruding clamping block 452 is assembled into the long hole corresponding to the second rail 20.

A disassembly trigger mechanism 3 is mounted at an end portion of the short pull rod 41 away from the second locking block 45, and the disassembly trigger mechanism 3 is mounted at a middle portion of the second rail 20; and when the first rail 10 and the second rail 20 are bidirectionally locked in the sliding direction, the disassembly trigger mechanism 3 is located outside an end portion of the first rail 10.

In this embodiment, the disassembly trigger mechanism 3 pulled by the short pull rod 41 in the disassembly unlocking mechanism 4 is arranged at the middle portion of the second rail 20, by manually applying a force to the disassembly trigger mechanism 3, unlocking of the second locking block 45 is achieved through force transmission; and compared with the force applied by the sliding-in trigger mechanism 1, the operation of the disassembly trigger mechanism 3 is finer, and manual operation is required, which conforms to the actual usage scenarios, and effectively avoids misoperation on the disassembly trigger mechanism 3.

The end portion of the short pull rod 41 extends to form a mounting portion 413, and the disassembly trigger mechanism 3 is a toggle block assembled on a side surface of the mounting portion 413; and the mounting portion 413 and a side surface attached to the toggle block are clamped and matched through a concave hole and a convex block, and a fastener is mounted towards the mounting portion 413 through the toggle block, so that stable and reliable mounting of the toggle block on the mounting portion 413 of the short pull rod 41 is achieved.

In this embodiment, through mounting of the toggle block on the mounting portion 413, the disassembly trigger mechanism 3 is formed, which facilitates performing force application operation on the end portion of the short pull rod 41.

In this embodiment, a third long hole 414 is formed through the mounting portion 413 and the toggle block, a fourth guide pin 46 is mounted on a side surface facing the second rail 20 through the third long hole 414, so that sliding mounting support of the mounting portion 413 of the short pull rod 41 relative to the second rail 20 is achieved.

In this embodiment, through the first locking block 25 and the second locking block 45 with a similar structure on the second rail 20, the layout of the corresponding sliding-in trigger mechanism 1 and the disassembly trigger mechanism 3 with a similar structure is combined, and the arrangement of the limiting protrusion 101 on the first rail 10 is matched, so that the reliable locking after the second rail 20 slides out relative to the first rail 10 is achieved, and moreover, through unlocking selection of the first locking block 25 or the second locking block 45, sliding-in unlocking or sliding-out disassembly unlocking of the second rail 20 relative to the first rail 10 can be achieved. The overall layout is reasonable and ingenious, and the structure is simplified, which facilitates implementation and actual use.

In this embodiment, a guide inclined surface 451 can further be arranged at the end portion, facing the limiting protrusion 101, of the second locking block 45. When the disassembled second rail 20 needs to be slidably mounted relative to the first rail 10, the limiting protrusion 101 applies force to the second locking block 45 through the guide inclined surface 451 to drive the second locking block 45 to move relative to the second rail 20, until the limiting protrusion 101 crosses the second locking block 45 to achieve the locking in the sliding-out state after the second locking block is remounted.

In this embodiment, the force transmission mechanism in the sliding-in unlocking mechanism 2 for unlocking the first locking block 25 is configured as the long push rod 21, and the sliding-in trigger mechanism 1 for driving the long push rod 21 to push is arranged at the end portion of the second rail 20, which facilitates the operation of switching from a locking state to a sliding-in state, and even the push plate 12 of the sliding-in trigger mechanism 1 can be pushed without using a hand.

In this embodiment, the force transmission mechanism in the disassembly unlocking mechanism 4 for unlocking the second locking block 45 is configured as the short pull rod 41, and the disassembly trigger mechanism 3 for driving the short pull rod 41 to pull is arranged in the middle portion of the second rail 20, which can be conveniently operated manually, so that the sliding rail is switched from the locking state to the sliding-out disassembly state, and through the ingenious layout of the operation position and the operation manner, accidental toggling of the short pull rod 41 is effectively avoided.

A method of using of the sliding rail having a locking, sliding-in, and disassembly opening-closing mechanism in this embodiment includes the following steps:
enabling a second rail 20 to slide out relative to a first rail 10 along a length direction until a limiting protrusion 101 on a side surface of the first rail 10 crosses a first locking block 25 on a side surface of the second rail 20, wherein the limiting protrusion 101 is clamped between the first locking block 25 and the second locking block 45, so that the second rail 20 is bidirectionally locked in a sliding direction relative to the first rail 10.

In a slide-out locking state of the second rail 20 relative to the first rail 10, an unlocking slide-in operation of the second rail 20 relative to the first rail 10 or an unlocking slide-out disassembly operation of the second rail 20 relative to the first rail 10 can be performed according to actual operation requirements.

The unlocking slide-in operation is: pushing a long push rod 21 in a sliding-in unlocking mechanism 2 to drive the first locking block 25 to move along a width direction of the second rail 20 to disengage from the locking of the limiting protrusion 101, so that the second rail 20 can slide in relative to the first rail 10; and specifically:
the push plate 12 extending out of the end portion thereof is pushed and forced along the length direction of the second rail 20, the push plate 12 pushes the long push rod 21, and through the wedge surface fit between the long push rod 21 and the first locking block 25, the first locking block 25 is driven to move relative to the width direction of the second rail 20, so that the first locking block 25 is disengaged from the locking limitation on the limiting protrusion 101.

The unlocking slide-out disassembly operation is: pulling a short pull rod 41 in a disassembly unlocking mechanism 4 to drive the second locking block 45 to move along the width direction of the second rail 20 to disengage from the locking of the limiting protrusion 101, so that the second rail 20 can continue to move along a slide-out direction relative to the first rail 10 until the second rail 20 is disengaged from the first rail 10 to achieve disassembly; and specifically:
manual force is applied to the disassembly trigger mechanism 3, the short pull rod 41 is pulled to move towards the outer end portion of the second rail 20, and through the wedge surface fit between the short pull rod 41 and the second locking block 45, the second locking block 45 is driven to move relative to the width direction of the second rail 20, so that the second locking block 45 is disengaged from the locking limitation on the limiting protrusion 101.

In this embodiment, the first rail 10 and the second rail 20 can be a middle rail and an inner rail in existing three-section rails, or an outer rail and a middle rail, or two rails in existing two-section rails, so that bidirectional locking in the sliding-out state between the two rails that slide mutually can be achieved, and unlocking of one direction in the bidirectional locking is achieved according to the operation requirement.

The present invention has reasonable and ingenious layout and simplified structure, and the sliding-in or disassembly operation can be achieved while reliable locking in a sliding-out state of the sliding rail is ensured. The operation is convenient and smooth, which greatly ensures and facilitates daily maintenance and use of a server, and has good practicability.

Various embodiments in the specification are described in a progressive manner, and each embodiment focuses on the differences from the other embodiments, and the same or similar parts between the various embodiments can refer to each other.

The above description is an explanation of the present invention and is not intended to limit the present invention. The scope limited by the present invention refers to the claims, and any form of modification may be made within the protection scope of the present invention.

What is claimed is:

1. A sliding rail having a locking, sliding-in, and disassembly opening-closing mechanism, comprising a first rail (10) and a second rail (20) slidably assembled relative to each other along a length direction, wherein a first locking block (25) and a second locking block (45) are mounted on a side surface of the second rail (20) facing the first rail (10) at intervals along a length direction; the first locking block (25) is driven by a sliding-in unlocking mechanism (2) to move in a width direction of the second rail (20), and the second locking block (45) is driven by a disassembly unlocking mechanism (4) to move in the width direction the second rail (20); and a limiting protrusion (101) is disposed on a side surface of the first rail (10) facing the second rail (20), and along with a relative sliding of the second rail (20) and the first rail (10) in the length direction, the limiting protrusion (101) is clamped between the first locking block (25) and the second locking block (45) to form bidirectional locking of the second rail (20) and the first rail (10) in a sliding direction.

2. The sliding rail having a locking, sliding-in, and disassembly opening-closing mechanism according to claim 1, wherein the sliding-in unlocking mechanism (2) comprises a long push rod (21) slidably arranged along a length direction of the second rail (20), an inner end of the long push rod (21) is located at the first locking block (25), a wedge surface fit is formed between an end portion of the long push rod (21) and the first locking block (25), and movement of the long push rod (21) in a length direction causes the first locking block (25) to move to unlock in the width direction of the second rail (20).

3. The sliding rail having a locking, sliding-in, and disassembly opening-closing mechanism according to claim 2, wherein a first guide structure and a first reset structure for relative sliding are mounted between the long push rod (21) and the second rail (20) as well as between the first locking block (25) and the second rail (20); and the end portion of the long push rod (21) facing the first locking block (25) is disposed as a first sliding-in inclined surface (213), and the first sliding-in inclined surface (213) and a second sliding-in inclined surface (251) on the first locking block (25) are assembled to form a wedge surface fit.

4. The sliding rail having a locking, sliding-in, and disassembly opening-closing mechanism according to claim 2, a sliding-in trigger mechanism (1) is mounted at an end portion of the second rail (20) located at an outer end of the long push rod (21), and the sliding-in trigger mechanism (1) pushes the long push rod (21) to move to cause the first locking block (25) to move.

5. The sliding rail having a locking, sliding-in, and disassembly opening-closing mechanism according to claim 4, wherein the sliding-in trigger mechanism (1) comprises a push plate (12) slidably mounted on a side surface at the end portion of the second rail (20), an inner side surface of the push plate (12) directly faces the outer end of the long push rod (21), and an outer side surface of the push plate (12) extends out of the second rail (20) and then turns over and extends to form a pushing portion (122); and a second guide structure and a second reset structure for relative sliding are mounted between the push plate (12) and the second rail (20).

6. The sliding rail having a locking, sliding-in, and disassembly opening-closing mechanism according to claim 1, wherein the disassembly unlocking mechanism (4) comprises a short pull rod (41) slidably arranged along the length direction of the second rail (20), the short pull rod (41) pass through the second locking block (45) along the length direction, a wedge surface fit is formed between the short pull rod (41) and the second locking block (45), and movement of the short pull rod (41) in the length direction causes the second locking block (45) to move to unlock in the width direction of the second rail (20).

7. The sliding rail having a locking, sliding-in, and disassembly opening-closing mechanism according to claim 6, wherein a third guide structure and a third reset structure for relative sliding are mounted between the second locking block (45) and the second rail (20), and a fourth guide structure for relative sliding is mounted between the short pull rod (41) and the second rail (20); and a first disassembly inclined surface (411) is formed in a middle portion of the short pull rod (41), a second through groove (455) for the short pull rod (41) to pass through is formed in the second locking block (45), and a second disassembly inclined surface (456) assembled with the first disassembly inclined surface (411) is formed on a side surface of the second through groove (455) to form a wedge surface fit.

8. The sliding rail having a locking, sliding-in, and disassembly opening-closing mechanism according to claim 6, wherein a disassembly trigger mechanism (3) is mounted at an end portion of the short pull rod (41) away from the second locking block (45), and the disassembly trigger mechanism (3) is mounted at a middle portion of the second rail (20); and when the first rail (10) and the second rail (20) are bidirectionally locked in the sliding direction, the disassembly trigger mechanism (3) is located outside an end portion of the first rail (10).

9. The sliding rail having a locking, sliding-in, and disassembly opening-closing mechanism according to claim 8, wherein the end portion of the short pull rod (41) extends to form a mounting portion (413), and the disassembly trigger mechanism (3) is a toggle block assembled on a side surface of the mounting portion (413); and the mounting portion (413) and a side surface attached to the toggle block are clamped and matched through a concave hole and a convex block, and a fastener is mounted towards the mounting portion (413) through the toggle block.

10. A method of using of the sliding rail having a locking, sliding-in, and disassembly opening-closing mechanism according to claim 1, comprising the following steps:
enabling a second rail (20) to slide out relative to a first rail (10) along a length direction until a limiting protrusion (101) on a side surface of the first rail (10) crosses a first locking block (25) on a side surface of the second rail (20), wherein the limiting protrusion (101) is clamped between the first locking block (25) and the second locking block (45), so that the second rail (20) is bidirectionally locked in a sliding direction relative to the first rail (10);
pushing a long push rod (21) in a sliding-in unlocking mechanism (2) to drive the first locking block (25) to move along a width direction of the second rail (20) to disengage from the locking of the limiting protrusion (101), so that the second rail (20) can slide in relative to the first rail (10); and
pulling a short pull rod (41) in a disassembly unlocking mechanism (4) to drive the second locking block (45) to move along the width direction of the second rail (20) to disengage from the locking of the limiting protrusion (101), so that the second rail (20) can continue to move along a slide-out direction relative to the first rail (10) until the second rail (20) is disengaged from the first rail (10) to achieve disassembly.
